(19) United States
(12) Patent Application Publication
(10) Pub. No.: US 2008/0121899 A1
(43) Pub. Date: May 29, 2008

(54) Transparent electrode for LED array

(75) Inventors: David G. Pires, Phoenix, AZ (US); Alan C. Thomas, Gilbert, AZ (US); Walter J. Paciorek, Phoenix, AZ (US); Ilona Budinavicius, Phoenix, AZ (US)

Correspondence Address: Paul F. Wille;Cantor Colburn LLP, 55 Griffin Road South, Bloomfield, CT, 06002, US

(73) Assignee: World Properties, Inc., Lincolnwood, IL (US)

(21) Appl. No.: 11/593,881

(22) Filed: Nov. 7, 2006

(51) Int. Cl. H01L 33/00; H01L 27/15; H01L 21/77

(52) U.S. Cl. 257/88; 438/28; 257/E27.121; 257/E21.598; 257/E33.059

(57) ABSTRACT

An array of light emitting diodes coupled between a substrate and a transparent electrode include a pair of equipotential bus bars supplying electrical current simultaneously to at least two light emitting diodes, each located in its own area of transparent conductive material. In accordance with another aspect of the invention, a linear array of light emitting diodes has an electrode that includes a conductive island for each light emitting diode and a bus bar interconnecting and surrounding the conductive islands.

### CROSS-REFERENCE TO RELATED APPLICATION

This application relates to application Ser. No. 11/193,305, filed Jul. 29, 2005, entitled Acicular ITO for LED Array, and assigned to the assignee of this invention. The contents of the filed application are incorporated by reference into this disclosure.

### FIELD OF THE INVENTION

This invention relates to light sources or displays utilizing an array of light emitting diodes (LEDs) and, in particular, to improving the uniformity of light emission from two or more LEDs by improving the conductive path that supplies electrical current to the LEDs.

### BACKGROUND OF THE INVENTION

For back lighting, display, and other applications, one wants as uniform a light source as possible, and therein lies a problem. LEDs have numerous advantages over incandescent lamps but, like incandescent lamps, are point sources of light. Various forms of light guides or light channels have been used to diffuse the light. An alternative is to provide a plurality of sources in an array. Depending upon the spacing of the LEDs, an object appears uniformly lit at some minimum distance from the array. In some applications, more often than not decorative, the point sources are acceptable but cost is a primary consideration.

Arrays of LEDs have long been known in the art. For example, U.S. Pat. No. 4,047,075 (Schoberl) discloses an array of LEDs made by simply stacking a plurality of packaged LEDs in a small volume. Packaged LEDs occupy considerably more volume than the semiconductor die or chip within the package. U.S. Pat. No. 4,335,501 (Wickenden et al.) discloses an array of LED dice on a single semiconductor substrate. U.S. Pat. No. 4,728,999 (Dannatt et al.) discloses a plurality of bus bars for powering subsets of diodes in an array. U.S. Pat. No. 6,595,671 (Lefebvre et al.) discloses an extra bus bar for providing a higher or lower voltage than another bus bar.

An LED is a non-linear device. Like most diodes, an LED does not conduct until a forward bias exceeds a threshold, e.g. 0.6 volts, and then conduction must be limited by some sort of ballast, typically a series resistance. Current is typically 10-60 ma. and brightness is roughly proportional to current. The color of the emitted light may also change with changes in current. As with any device, LEDs produce heat. Unfortunately, LEDs typically have a negative temperature coefficient of resistance, which means that current increases with temperature. Thus, controlling current is important for several reasons.

Two LEDs of the same type number do not necessarily have the same electrical characteristics. If a single resistor is used as ballast for two parallel LEDs, then the failure of one LED can result in the second LED being overdriven (too much current) and, consequently, failing soon thereafter. Larger arrays, with LEDs in series and in parallel have the same problem, only compounded by a greater number of LEDs. Although it is separately well known in the art that current through an LED must be carefully controlled, many of the patents on arrays of LEDs have a paucity of disclosure on how to drive the array, except to limit or to “condition” current in some undisclosed manner. It may be that uniform brightness is not a concern or is too difficult to achieve in the disclosed configurations.

A material referred to as acicular ITO (indium tin oxide) is known in the art as a transparent conductor; see U.S. Pat. No. 5,580,496 (Yukinobu et al.) and the divisional patents based thereon (U.S. Pat. Nos. 5,820,843, 5,833,941, 5,849,221). Acicular ITO has a fibrous structure composed of 2-5 μm thick by 15-25 μm long ITO needles. The needles are suspended in an organic resin, e.g. polyester. Acicular ITO is different in kind from other forms of the material. A cured, screen printed layer of acicular ITO is approximately five times more conductive than conventional layers containing ITO powder but is about two thirds less conductive than sputtered ITO, which is more difficult to pattern than screen printable materials.

Even assuming that there is uniform conductivity in the transparent electrode, the placement of die on an electrode can greatly affect luminance. The current spreads through the electrode, flowing through an area to the die. Placement can affect the effective area. Because transparent conductors generally have lower conductivity than opaque conductors, a bus bar is often used to provide a low resistance path along one or more sides of an array. Unfortunately, a bus bar exaggerates the problem of die placement because a slight misplacement can, for example, increase the distance to the nearest bus bar by ten percent or more. The increase in distance causes a disproportionate decrease in current and brightness. U.S. Pat. No. 7,052,924 (Daniels et al.) discloses a conductive grid overlying an ITO coated substrate and an LED located in each grid section. While suited for some applications, an ITO coated substrate is expensive and does not allow for adjusting the current to each LED.

In view of the foregoing, it is therefore an object of the invention to reduce the effect of die placement on uniformity of luminosity.

Another object of the invention is to provide an improved transparent, conductive electrode for diode arrays.

A further object of the invention is to provide an array of LEDs that has a more uniform ballast resistance associated with each LED.

Another object of the invention is to provide an array of LEDs that are substantially uniformly bright when lit, either simultaneously or in subsets of the entire array.

A further object of the invention is to provide an array of LEDs in which the failure of one LED has substantially no effect the brightness of other LEDs in the array.

Another object of the invention is to provide an array of LEDs that can be manufactured at lower cost than in the prior art.

### SUMMARY OF THE INVENTION

The foregoing objects are achieved in this invention wherein an array of light emitting diodes coupled between a substrate and a transparent electrode include a pair of equipotential bus bars supplying electrical current simultaneously to at least two light emitting diodes, each located in its own area of transparent conductive material. In accordance with another aspect of the invention, a linear array of light emitting diodes has an electrode that includes a conductive island for each light emitting diode and a bus bar interconnecting and surrounding the conductive islands.

### BRIEF DESCRIPTION OF THE DRAWINGS

A more complete understanding of the invention can be obtained by considering the following detailed description in conjunction with the accompanying drawings, in which:

FIG. 1 is a cross-section of a pair of LEDs in an array constructed in accordance with the prior art;

FIG. 2 is a plan view of LEDs in an array constructed in accordance with the prior art;

FIG. 3 is a plan view of LEDs in an array constructed in accordance with a preferred embodiment of the invention;

FIG. 4 is a plan view of LEDs in an array constructed in accordance with an alternative embodiment of the invention;

FIG. 5 is a plan view of a linear LED array constructed in accordance with the prior art;

FIG. 6 is a plan view of a linear LED array constructed in accordance with another aspect of the invention;

FIG. 7 is a cross-section of a linear LED array constructed in accordance with the invention;

FIG. 8 is a cross-section of an array constructed in accordance with the invention; and

FIG. 9 is a cross-section of an array constructed in accordance with the invention and illustrates an alternative sequence for depositing layers.

### DETAILED DESCRIPTION OF THE INVENTION

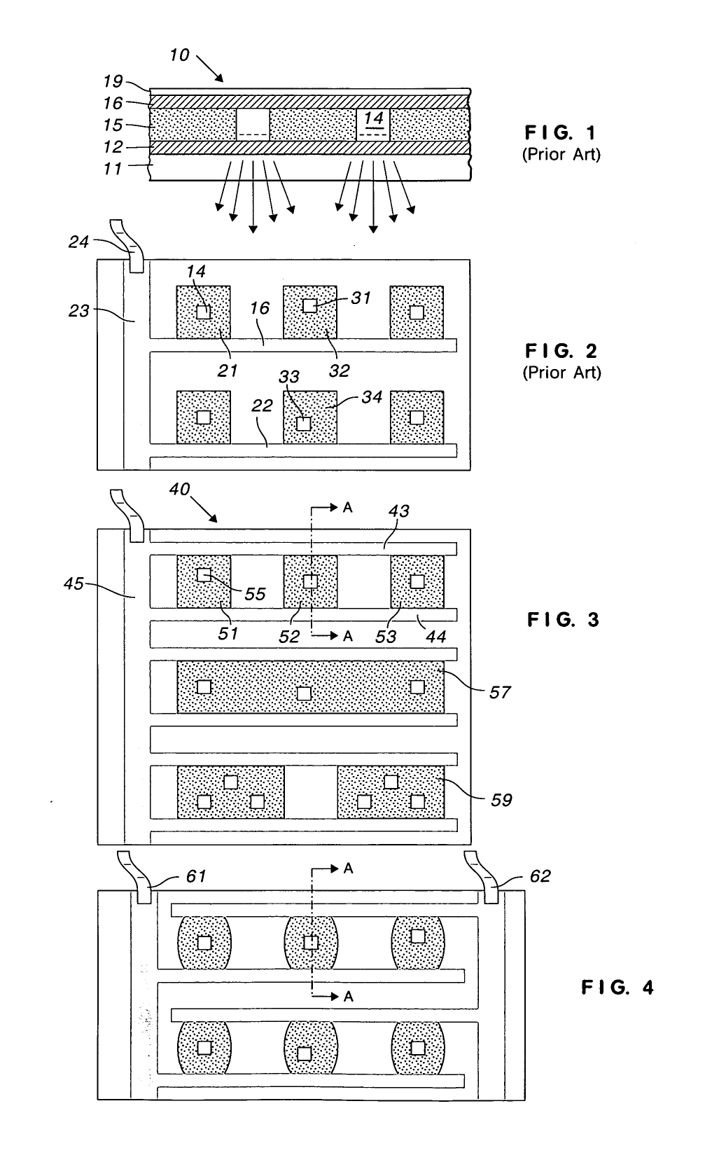

FIG. 1 is a cross-section of a pair of LEDs in an array constructed in accordance with the prior art. Array 10 includes transparent substrate 11 of polyester or polycarbonate material. A transparent, front electrode (not shown in FIG. 1) of indium tin oxide having a thickness of 1000 Å or overlies substrate 11 to provide electrical contact to the die. Bus bar 12 overlies the transparent conductor, increasing the conductivity of the area. Bus bar 12 is typically screen printed from a silver bearing ink, although other conductive particles can be used instead, e.g. carbon. Die 14 has an area of a first conductivity, generally p-type, in contact with the transparent conductor near bus bar 12. The region between LEDs is filled with a suitable dielectric, such as epoxy. Bus bar 16 and insulating layer 19 overlie the die as shown. Bus bar 16 provides electrical contact to the n-region of die 14. The construction of the array can be symmetric about the dice, i.e. layer 19 can be the same material, if not the same thickness, as layer 11 and bus bar 16 can be the same material as bus bar 12, e.g., silver particles that are screen printed in suitable matrix, such as fluoropolymer, polyester, vinyl, epoxy.

FIG. 2 is a plan view of LEDs in an array constructed in accordance with the prior art, as though one were looking up into the array in FIG. 1. In a plan view, the substrate and the rear electrode are not seen. LED 14 is in contact with transparent conductive layer 21, which, in turn, is in contact with bus bar 16. Bus bar 16 and bus bar 23 are connected together by feed 23 and coupled to lead 24, which provides external connection to the array.

As illustrated, somewhat exaggeratedly, in FIG. 2, LED 31 is off-center under transparent conductor 32 and LED 33 is off-center under transparent conductor 34. Because LED 31 is further from bus bar 16 than the other LEDs, it will be somewhat dimmer, even for allowing for differences in light emission among the LEDs in the array. LED 33 is closer to bus bar 22 than the other LEDs and will be brighter because the current path has a lower resistance.

Bus bars improve brightness, by reducing resistance, but make die placement more critical. A slight misplacement can be a significant fraction of the length of the current path to a bus. One could make the contact areas larger and move the bus bars further away from the LEDs but this is counterproductive. Many transparent conductors other than sputtered ITO are available but are expensive.

In accordance with one aspect of the invention, illustrated in FIG. 3, a pair of bus bars is coupled to the same electrode of at least two LEDs. Bus bars 43 and 44 have substantially the same voltage thereon, supplied by feed 45. The bus bars can extend in the same direction, as illustrated in FIG. 3, or extend in different directions, as illustrated in FIG. 4. Conductive areas, such as areas 51, 52, and 53 are preferably screen printed from a conductive ink, such as Baytron® conductive polymer, Orgacon™ conductive polymer (PEDOT—polyethylene dioxythiophene), or particles of indium oxide, ITO, acicular ITO, gallium doped zinc oxide, or aluminum doped zinc oxide in a suitable polymer. Bus bars 43 and 44 can be printed over the edges of the areas or the areas can be printed between the bus bars, using the bus bars for definition.

If an LED is located closer to one bus bar than the other, the changes in current paths are compensating. For example, LED 55 is located closer to bus bar 43 than to bus bar 44. The current from LED 55 to bus bar 43 increases while the current from LED 55 to bus bar 44 decreases. The sum of the currents is substantially constant. Thus, a misplaced LED is as bright as its neighbors, other factors being equal.

When other factors are not equal, for example, an LED needing a ballasting resistor having a resistance slightly different from other LEDs, the electrode can be trimmed as disclosed in the above-identified co-pending application. This could occur, for example, if LEDs having different color were used in a single array. Different colors can be produced instead by including cascading material, such as phosphor or dye, in the transparent conductive layer. Different colors can also be produced by including cascading material in a layer printed over the transparent conductive layer.

The conductive areas can be bounded by closed curves or polygons. Preferably, the line of contact between a bus bar and the conductive area exceeds the diameter of the LED. The line of contact can be curved, jagged, or straight. In FIG. 3 the conductive areas are substantially square. In FIG. 4, the conductive areas have curved boundaries. Also in FIG. 4, two feeds are used, with separate leads, 61 and 62. The bus bars are interdigitated; that is, they alternate and extend in opposite directions. Leads 61 and 62 are connected to the same power source, although one lead can be left floating for dimming.

The rear electrode, not shown, provides the second electrical connection to the LEDs. The rear electrode can be any conductive layer, transparent or opaque, and can be reflective. A metal layer, such as copper or aluminum, can be used or a layer can be screen printed from conductive ink, such as an ink containing particles of carbon, silver, tin oxide, or indium tin oxide. The rear electrode can be a conductive area on a printed circuit board or on a “flex circuit.”

In FIG. 3, LEDs between a pair of equipotential bus bars can share a common transparent electrode, such as electrode 57. This can simplify the screen printing without unduly increasing the print area. Because of the dual bus bars, one can locate LEDs as desired under a transparent electrode. For example, the LEDs in contact with transparent conductor 59 can be placed asymmetrically and can emit different colors, e.g. red, green, and blue.

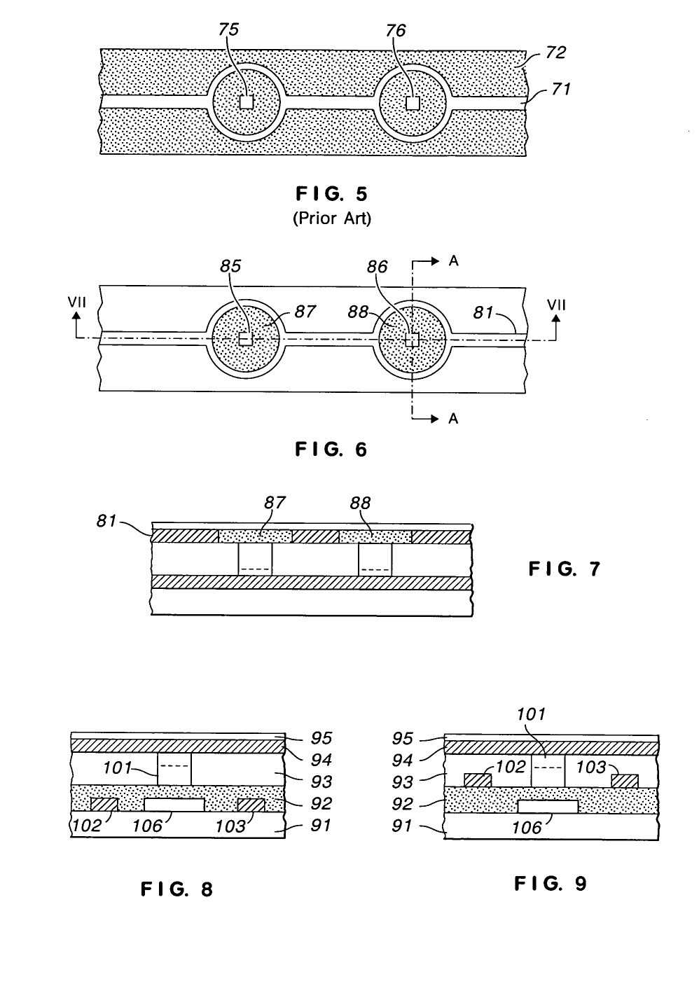

FIG. 5 is a plan view of a linear array constructed in accordance with the prior art. FIG. 6 is a plan view of a linear array constructed in accordance with another aspect of the invention. FIG. 7 is a cross-section of an array constructed as illustrated in FIG. 6.

In FIG. 5, bus bar 71 overlies transparent conductive layer 72, which overlies LEDs 75 and 76. The area covered by transparent conductive layer 72 is significant. By comparison, in FIG. 6 LEDs 85 and 86 underlie transparent conductive islands 87 and 88. Bus bar 81 interconnects and surrounds the islands to provide reduce resistivity. Constructing the linear array of FIG. 6 in accordance with the invention is significantly less expensive than constructing the array illustrated in FIG. 5 because far less material is used for the transparent conductive areas.

FIG. 8 and FIG. 9 represent cross-sections that can be taken along line A-A in FIG. 3, FIG. 4, or FIG. 6 and illustrate processes for making an LED array in accordance with the invention. In FIG. 8, bus bars 102 and 103 are deposited on substrate 91, e.g. by screen printing. A region of cascading material, represented by area 106 is also deposited on substrate 91. Either the bus bars or the cascading material can be deposited first. Transparent, conductive layer 92 is then deposited and at least touches the bus bars. Preferably, layer 92 overlaps the bus bars, as illustrated. LED 101 is positioned on layer 92 and surrounded with insulator 93. Rear electrode 94 and insulating or protective layer 95 are then applied.

The array is thus built. “top down” rather than “bottom up,” which can lead to some confusion because the device is usually described as though the array were constructed “bottom up” or back to front. For example, cascading material layer 106 is “on” transparent conductive layer 92. Similarly, the transparent conductor is “on” or “overlies” LED 101. Those of ordinary skill in the art understand that the device is built the other way around and there is no confusion.

FIG. 9 illustrates an alternative method of assembly in which bus bars 102 and 103 are applied after transparent conductive layer 92. In this process, region 106 must be deposited first because LED 101 must contact layer 92. It is not necessary that bus bars 102 and 103 be deposited prior to placing LED 101 but it is preferred because the bus bars provide a reference for locating the LED. Insulating layer 93, rear electrode 94 and insulating layer 95 are then applied as in the process illustrated in FIG. 8.

The invention thus provides a reliable, consistent connection to LEDs using a reduced area of expensive, transparent, conductive material for one electrode. The invention also reduces the effect of die placement on uniformity of luminosity, enabling one to obtain an array of LEDs that are substantially uniformly bright when lit, either simultaneously or in subsets. The failure of one LED has substantially no effect the brightness of other LEDs in the array because of individual ballasting and dual connections. For LEDs in contact with individual transparent electrodes, LEDs of different current ratings can be accommodated by adjusting the geometry of the transparent conductor, by using different material for some of the transparent conductors, or by combinations thereof.

Having thus described the invention, it will be apparent to those of skill in the art that various modifications can be made within the scope of the invention. For example, although illustrated with 2×3 arrays, dual bus bars can be used for linear arrays (1×n) as well.

What is claimed as the invention is:

1. In an array of light emitting diodes coupled between a substrate and a transparent electrode, the improvement comprising:
a pair of equipotential bus bars supplying electrical current simultaneously to at least two light emitting diodes.

2. The array as set forth in claim 1 wherein the pair of equipotential bus bars supply electrical current to the transparent electrode.

3. The array as set forth in claim 1 wherein the bus bars extend in the same direction.

4. The array as set forth in claim 1 wherein the bus bars extend in different directions.

5. The array as set forth in claim 1 wherein the bus bars are interdigitated.

6. The array as set forth in claim 1 wherein the bus bars are co-planar.

7. The array as set forth in claim 1 wherein at least two light emitting diodes are coupled to a bus bar by a patterned layer of transparent conductor.

8. The array as set forth in claim 7 wherein at least one light emitting diode emits light having a color different from the light emitted by another light emitting diode.

9. The array as set forth in claim 7 wherein the transparent conductor is acicular ITO.

10. The array as set forth in claim 7 wherein the layer of transparent conductor includes cascading material.

11. The array as set forth in claim 7 and further including a layer of cascading material on the transparent conductor.

12. A linear array of light emitting diodes including a plurality of light emitting diodes in a row between two electrodes, characterized in that:
one of the electrodes includes a transparent, conductive island for each light emitting diode and a bus bar interconnecting and surrounding the transparent, conductive islands.

13. The linear array as set forth in claim 12 wherein the islands are a patterned layer of screen printed material selected from the group consisting of:
conductive polymer, and
particles of indium oxide, ITO, acicular ITO, ZnO:Ga, or ZnO:Al in a polymer.

14. The array as set forth in claim 12 wherein at least one island includes cascading material.

15. The array as set forth in claim 12 and further including a layer of cascading material on at least one island.

16. A method of making an array of light emitting diodes, said method comprising the steps of:
a) depositing regions of cascading materials on a transparent substrate;
b) depositing areas of transparent conductive material on the substrate, wherein each area at least partially overlies a region;
c) depositing at least one bus bar in contact with the areas of transparent conductive material;
wherein step c) can occur before or after step a) or before or after step b);
d) placing at least one light emitting diode in electrical contact with each area;
e) depositing an insulating layer around the light emitting diodes; and
f) depositing a rear electrode in electrical contact with said light emitting diodes.

17. The method as set forth in claim 16 wherein step c) includes depositing two bus bars in contact with each area of transparent conductive material.
